(19) United States
(12) Patent Application Publication
(10) Pub. No.: US 2022/0394876 A1
(43) Pub. Date: Dec. 8, 2022

(54) POWER CONTROLLER APPARATUS

(71) Applicant: DENSO CORPORATION, Kariya-city (JP)

(72) Inventors: Yuuta HASHIMOTO, Kariya-city (JP); Kazuya TAKEUCHI, Kariya (JP)

(73) Assignee: DENSO CORPORATION, Kariya-city (JP)

(21) Appl. No.: 17/885,819

(22) Filed: Aug. 11, 2022

Related U.S. Application Data
(63) Continuation of application No. PCT/JP2021/003555, filed on Feb. 1, 2021.

(30) Foreign Application Priority Data
Feb. 14, 2020 (JP) 2020-023566

(51) Int. Cl. H05K 7/20; H05K 7/12; H02M 7/48; H01L 23/40

(52) U.S. Cl. CPC H05K 7/2039; H05K 7/12; H02M 7/48; H01L 23/40; H05K 7/20945

(57) ABSTRACT

The power controller apparatus includes a plurality of parts including a heat member and a heat dissipation member. The power controller apparatus includes a housing for accommodating these plurality of parts. The power controller apparatus includes a snap fit and a thermal conductive member. The snap fit connects the heat member and the heat dissipation member. The thermal conductive member is arranged between the heat member and the heat dissipation member. The thermal conductive member includes a filler having anisotropy with respect to thermal conductivity. The filler is oriented so as to exhibit high thermal conductivity in a stacking direction between the heat member and the heat dissipation member.

### CROSS REFERENCE TO RELATED APPLICATIONS

The present application is a continuation application of International Patent Application No. PCT/JP2021/003555 filed on Feb. 1, 2021, which designated the U.S. and claims the benefit of priority from Japanese Patent Application No. 2020-023566 filed on Feb. 14, 2020, the entire disclosure of the above application is incorporated herein by reference.

### TECHNICAL FIELD

The present disclosure relates to a power controller apparatus.

### BACKGROUND

A power controller apparatus, including a power converter and/or power inverter, needs a plurality of components. Therefore, assembling the components is an important aspect to provide a power controller apparatus which meets a market demand. On the other hand, the power controller apparatus is required to manage thermal demand. For example, the power controller apparatus dissipates heat to manage a temperature of a component. In the above aspects, or in other aspects not mentioned, there is a need for further improvements in a power controller apparatus.

### SUMMARY

The power controller apparatus disclosed herein includes a plurality of parts. The plurality of parts at least includes a heat member which requires heat dissipation by generating heat or receiving heat, and a heat dissipation member which contributes to dissipate heat from the heat member. The power controller apparatus includes a snap fit which connects the heat member and the heat dissipation member, and the thermal conductive member arranged between the heat member and the heat dissipation member. The thermal conductive member includes a filler which has anisotropy with respect to thermal conductivity, and is oriented so as to exhibit high thermal conductivity in a stacking direction between the heat member and the heat dissipation member.

According to the disclosed power controller apparatus, the heat member and the heat dissipation member are connected by a snap fit. Moreover, between the heat member and the heat dissipation member, a thermal conductive member having a filler oriented so as to exhibit high thermal conductivity in a stacking direction is arranged. As a result, the heat member and the heat dissipation member can be connected by the snap fit, and good thermal transfer be obtained between the heat member and the heat dissipation member.

Disclosed embodiments herein employ different technical means to achieve their respective objectives. The objectives, features, and effects disclosed herein is further clarified by reference to the subsequent detailed description and accompanying drawings.

### BRIEF DESCRIPTION OF DRAWINGS

The disclosure is further described with reference to the accompanying drawings in which:

FIG. 1 is a block diagram of a power controller apparatus according to a first embodiment;

FIG. 2 is a cross-sectional view showing a heat member and a heat dissipation member;

FIG. 3 is an enlarged cross-sectional view showing a thermal conductive member;

FIG. 4 is an exploded view showing a heat member, a thermal conductive member, and a heat dissipation member;

FIG. 5 is a cross sectional view showing a heat member and a heat dissipation member according to a second embodiment;

FIG. 6 is a cross sectional view showing a heat member and a heat dissipation member according to a third embodiment; and

FIG. 7 is a cross sectional view showing a heat member and a heat dissipation member according to a fourth embodiment.

### DETAILED DESCRIPTION

A plurality of embodiments are described with reference to the drawings. In some embodiments, parts that are functionally and/or structurally corresponding to each other and/or associated with each other are given the same reference numerals, or reference numerals with different hundred digit or more digits. For corresponding parts and/or associated parts, reference can be made to the description of other embodiments.

JP6189798B discloses a power controller apparatus. In this document, it is described that “Fixing methods between each member and the housing 50 include fastening with screws, welding such as TIG welding and laser welding, joining by ultrasonic waves and friction stirring, brazing, snap-fitting, press-fitting, etc.” The disclosure of JP6189798B is incorporated herein by reference to explain technical elements presented herein.

In a power controller apparatus, thermal resistance between a member that generates heat and a member that provides a heat dissipation path may hinder heat dissipation. From the viewpoint described above or from other unmentioned viewpoints, there is a demand for further improvement to the power controller apparatus.

It is an object disclosed is to provide a power controller apparatus which that achieves both ease of assembly work and suppression of thermal resistance.

### First Embodiment

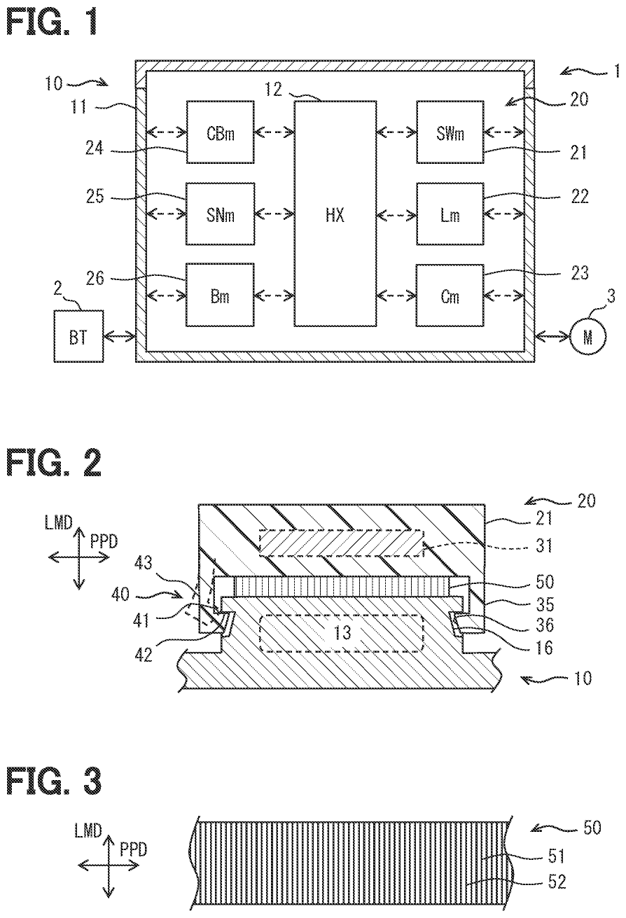

In FIG. 1, a power controller apparatus 1 is illustrated. The power controller apparatus 1 transforms electric power between a battery 2 and a rotary electric machine 3. Further, the power controller apparatus 1 may transform electric power between an external power source and the battery 2. The power controller apparatus 1 may be referred to as a power transforming apparatus or a power conditioner. The power controller apparatus 1 adjusts a voltage and current of the electric power supplied from the battery 2 and supplies the electric power to the rotary electric machine 3. Further, the power controller apparatus 1 adjusts a voltage and current of the electric power supplied from the rotary electric machine 3 and supplies the electric power to the battery 2. The power controller apparatus 1 is mounted on a vehicle such as an electric vehicle or a hybrid vehicle, for example. The vehicle is a car, a ship, or an aircraft. The power controller apparatus 1 constitutes a power conversion circuit including an inverter circuit and/or a converter circuit.

The power controller apparatus 1 includes a heat dissipation member 10 for providing a heat dissipation path for releasing waste heat such as Joule heat. The heat dissipation member 10 may be provided by, for example, the housing 11 of the power controller apparatus 1. The housing 11 may have a main body as a container and a cover as a lid. The body and the cover may be connected by a snap fit described later. The heat dissipation member 10 may be provided by, for example, a heat exchange member (HX) 12 that utilizes a heat exchange medium. The heat exchange member 12 is provided by a flow path or a heat exchanger. The heat exchange medium is provided by, for example, air, water, gas, or the like. The heat exchange member 12 is provided by, for example, a heat exchanger in which cooling water circulates. The heat dissipation member 10 may include only the housing 11, only the heat exchange member 12, or both the housing 11 and the heat exchange member 12.

The power controller apparatus 1 includes a plurality of components for constituting a power conversion circuit. Most of these plurality of parts are heat members 20. The heat member 20 require heat dissipation due to generating heat by itself or receiving heat from other parts. The heat member 20 may be referred to as a heat generating and/or receiving member, a high temperature member or a heat source member. The heat member 20 may be referred to as a heat generating member. A typical heat member 20 generates Joule heat by electric resistance. The heat member 20 needs heat dissipation in order to avoid an excessive temperature rise. In this specification, a component that becomes hot due to receiving heat from another member and needs to dissipate heat is also referred to as the heat member 20. The plurality of arrows with dashed line in FIG. 1 indicate a main thermal transfer paths in the power controller apparatus 1. A part of the heat to be discharged is dissipated from the heat member 20 via the heat dissipation member 10. A part of the heat to be discharged may be dissipated from one heat member 20 via another adjacent heat member 20 and further via the heat dissipation member 10. Therefore, the power controller apparatus 1 includes the heat dissipation member 10 that contributes to heat dissipation. The power controller apparatus 1 includes a plurality of heat members 20. The power controller apparatus 1 includes one or a plurality of heat dissipation members 10.

The power controller apparatus 1 includes a switch module (SWm) 21 as a heat member 20. The switch module 21 includes a semiconductor switch element. The semiconductor switch element is provided by a power MOSFET, an IGBT, a SiC element, or the like. The switch module 21 includes at least one semiconductor switch element. The switch module 21 may include a plurality of semiconductor switch elements. The switch module 21 provides a switch element in an inverter circuit or a converter circuit. The switch module 21 includes a resin member that encloses at least one semiconductor switch element. The resin member makes it possible to handle a plurality of members as one module. The power controller apparatus 1 may include one or a plurality of switch modules 21. The switch module 21 is directly or indirectly thermally coupled to the housing 11 as the heat dissipation member 10 and/or the heat exchange member 12. In many cases, the switch module 21 is configured to dissipate heat towards at least the heat exchange member 12.

The power controller apparatus 1 includes an inductor module (Lm) 22 as a heat member 20. The inductor module 22 includes an inductive electrical component including a coil. The inductor module 22 includes at least one inductor (coil element). The inductor provides an inductance in an inverter circuit or a converter circuit. The inductor module 22 may include a plurality of inductors. The inductor module 22 includes a resin member that encloses at least one inductor. The resin member makes it possible to handle a plurality of members as one module. The power controller apparatus 1 may include one or a plurality of inductor modules 22. The inductor module 22 is directly or indirectly thermally coupled to the housing 11 as the heat dissipation member 10 and/or the heat exchange member 12.

The power controller apparatus 1 includes a capacitor module (Cm) 23 as a heat member 20. The capacitor module 23 includes a capacitive element including a capacitor. The capacitor module 23 includes at least one capacitor. The capacitor module 23 may include a plurality of capacitors. The capacitor module 23 provides a smoothing circuit element in an inverter circuit or a converter circuit. The capacitor module 23 includes a resin member that encloses at least one capacitor. The resin member makes it possible to handle a plurality of members as one module. The power controller apparatus 1 may include one or a plurality of capacitor modules 23. The capacitor module 23 is directly or indirectly thermally coupled to the housing 11 as the heat dissipation member 10 and/or the heat exchange member 12.

The power controller apparatus 1 includes a circuit module (CBm) 24 as a heat member 20. The circuit module 24 includes a drive circuit for driving a semiconductor switching element. The circuit module 24 may include a control circuit such as a voltage monitoring circuit, a current monitoring circuit, and a microcomputer. The circuit module 24 may have a plurality of circuit elements including a circuit board and electric elements. The circuit module 24 includes a circuit board on which at least one circuit element is mounted. The power controller apparatus 1 may include one or a plurality of circuit modules 24. The circuit module 24 is directly or indirectly thermally coupled to the housing 11 as the heat dissipation member 10 and/or the heat exchange member 12.

The power controller apparatus 1 includes a sensor module (SNm) 25 as a heat member 20. The sensor module 25 includes a current sensor for detecting a current in a power conversion circuit. The current sensor may be provided in various types such as a shunt resistance type and a magnetic field sensing type. The sensor module 25 may include a plurality of current sensors. The sensor module 25 includes a resin member that encloses at least one current sensor. The sensor module 25 may include a bus bar through which a current to be detected flows. The resin member makes it possible to handle a plurality of members as one module. The power controller apparatus 1 may include one or a plurality of sensor modules 25. The sensor module 25 is directly or indirectly thermally coupled to the housing 11 as the heat dissipation member 10 and/or the heat exchange member 12.

The power controller apparatus 1 includes a bus bar module (Bm) 26 as a heat member 20. The bus bar module 26 includes a bus bar that provides a current path for the power conversion circuit. The bus bar module 26 includes at least one bus bar. The bus bar module 26 may include a plurality of bus bars. The bus bar module 26 includes a resin member that encloses at least one bus bar. The resin member makes it possible to handle a plurality of members as one module. The power controller apparatus 1 may include one or more bus bar modules 26. The bus bar module 26 is directly or indirectly thermally coupled to the housing 11 as the heat dissipation member 10 and/or the heat exchange member 12.

In FIG. 2, the heat dissipation member 10 and the heat member 20 are shown. The drawing shows a regular position of the heat dissipation member 10 and the heat member 20. The regular position indicates a state in which the power conversion circuit is functioning. Therefore, the regular position indicates the state after assembly. The regular position is also called the assembled position.

The heat dissipation member 10 is the housing 11 or the heat exchange member 12. In the case that the heat dissipation member 10 is the heat exchange member 12, the heat dissipation member 10 defines a medium passage 13 through which a heat transferring medium such as air or water flows. In the case that the heat dissipation member 10 is the housing 11, the heat dissipation member 10 does not include the medium passage 13. In the case that the heat dissipation member 10 is the housing 11, the heat dissipation member 10 may include a heat exchange promoting member such as fins.

The heat member 20 is a switch module 21. The switch module 21 houses a semiconductor switch element as an electric component 31 in a resin material. The illustrated electrical component 31 is completely wrapped in a resin material. Alternatively, the electrical component 31 may be partially wrapped in the resin material and partially exposed from the resin material. The electric component 31 may have an exposed portion for heat dissipation, for example.

The power controller apparatus 1 includes a snap fit 40. The heat dissipation member 10 and the heat member 20 are connected by the snap fit 40 at a regular position shown in the figure. The snap fit 40 holds and keeps two members to be connected in an engaged state. The snap fit 40 utilizes the elastic force of one or both of the two members to be connected. The snap fit 40 maintains the engaged state by utilizing an elastic force.

The snap fit 40 has an engaging step portion 41 and an engaging step portion 42. By placing the engaging step portion 41 and the engaging step portion 42 in contact with each other, the heat dissipation member 10 and the heat member 20 are placed in an engaged state. The surface provided by the engaging step portion 41 and the surface provided by the engaging step portion 42 face each other. The heat dissipation member 10 and the heat member 20 are arranged in a multiple layered manner with respect to the stacking direction LMD. The heat dissipation member 10 and the heat member 20 have a flat surface portion spreading in an orthogonal direction PPD orthogonal to the stacking direction LMD. The surface provided by the engaging step portion 41 is a plane spreading in the orthogonal direction PPD. The surface provided by the engaging step portion 42 is a surface spreading in the orthogonal direction PPD.

The snap fit 40 has an elastic piece 43 to provide an elastic force. The elastic piece 43 has an engaging step portion 41. The snap fit 40 may include other elastic pieces having an engaging step portion 42. The elastic piece 43 is provided by an elastic arm 35 extending from the heat member 20. The engaging step portion 41 is provided by an engaging protrusion 36 extending from the elastic arm 35. The engaging step portion 42 is provided by an engaging recess 16 formed on the heat dissipation member 10. The engaging step portion 41, the engaging step portion 42, and the elastic piece 43 in the snap fit 40 can be provided by various protrusion and recess shapes. Alternative to the illustrated example, the heat dissipation member 10 may be provided with an elastic arm. The engaging convex portion 36 and the engaging concave portion 16 may be arranged in an opposite relation. For example, the elastic arm 35 may be provided with an engaging concave portion, and the heat dissipation member 10 may be provided with an engaging convex portion. The snap fit 40 has an engaging step portion 41 provided by an engaging convex portion 36 disposed on the heat member 20 which is one of the heat member 20 and the heat dissipation member 10. The snap fit 40 has an engaging step portion 42 provided by a recess 16 disposed on the heat dissipation member 10 which is the other one of the heat member 20 and the heat dissipation member 10. The snap fit 40 fixes the heat member 20 and the heat dissipation member 10 by catching and hooking the two engaging step portions 41 and 42 each other.

The snap fit 40 catches and hooks the engaging step portion 41 and the engaging step portion 42 each other. The snap fit 40 maintains the engagement between the engaging step portion 41 and the engaging step portion 42 by an elastic force of the elastic piece 43. The snap fit 40 fixes the relative position between the heat dissipation member 10 and the heat member 20.

The power controller apparatus 1 includes a thermal conductive member 50. The thermal conductive member 50 is sandwiched between the heat dissipation member 10 and the heat member 20. The thermal conductive member 50 is arranged between the heat dissipation member 10 and the heat member 20. The thermal conductive member 50 enables thermal transfer between the heat dissipation member 10 and the heat member 20, and also enables a high thermal transfer coefficient. The thermal conductive member 50 itself has a high thermal conductivity. The thermal conductive member 50 is in close contact with both the heat dissipation member 10 and the heat member 20. This close contact state is maintained by the elastic force provided by the snap fit 40. The thermal conductive member 50 is also referred to as TIM (Thermal Interface Material). The thermal conductive member 50 has a flat shape that can be called a plate shape or a film shape. The thermal conductive member 50 has anisotropy with respect to thermal conductivity. A thermal conductivity of the thermal conductive member 50 with respect to the stacking direction LMD is higher than a thermal conductivity of the thermal conductive member 50 with respect to the orthogonal direction PPD.

In FIG. 3, the thermal conductive member 50 has a base material 51 and a filler 52. The base material 51 can be provided by a solid material such as elastomer or a semi-solid material such as silicon grease. In the drawing, the filler 52 is modeled and shown by a plurality of vertical lines. The filler 52 has anisotropy with respect to thermal conductivity. Anisotropy as used herein means that the filler 52 has a plurality of thermal conductivities depending on its shape. The filler 52 has at least a longitudinal direction and a lateral direction. The filler 52 has a higher thermal conductivity in the longitudinal direction than a thermal conductivity in the lateral direction. The filler 52 is oriented so as to exhibit high thermal conductivity in the stacking direction LMD between the heat member 20 and the heat dissipation member 10. The orientation in the present specification means a state in which the postures of a large number of fillers 52 are oriented in a predetermined direction.

The filler 52 is a fibrous member. The fibrous filler 52 is oriented so that the longitudinal direction of the fibers and the laminating direction LMD coincide with each other. The filler 52 is elastically deformed by force applied by the snap fit 40. In other words, the filler 52 is a member possible to be elastically deformed in a length direction by a fixing force acting between the heat dissipation member 10 and the heat member 20. The filler 52 is provided by carbon nanotubes (CNTs). Alternatively, the filler 52 can be provided by a variety of materials such as metallic whiskers, rod crystals and the like.

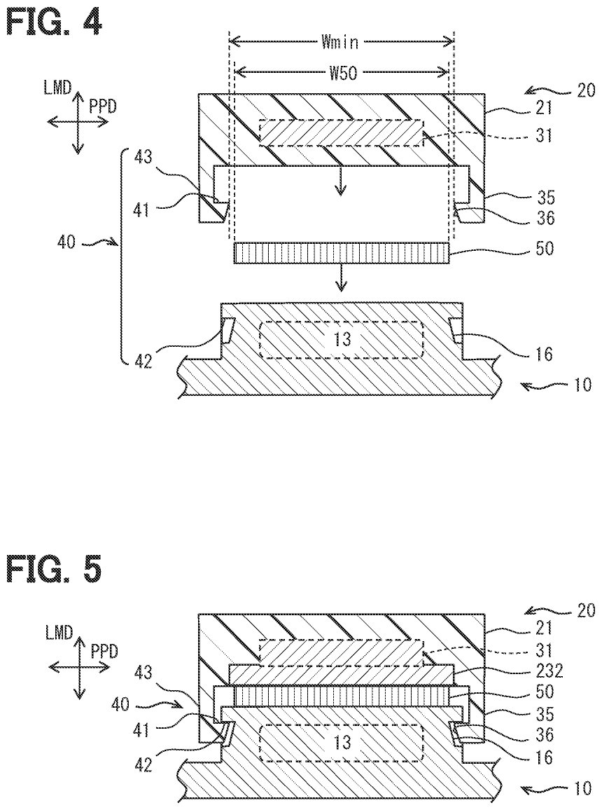

In FIG. 4, the manufacturing method of the power controller apparatus 1 includes a snap fit step of connecting the heat dissipation member 10 and the heat member 20 by the snap-fit 40. The snap fitting step may include connecting the body of the housing 11 and the cover with the snap fit 40. The manufacturing method of the power controller apparatus 1 includes an arranging step of arranging the thermal conductive member 50 between the heat dissipation member 10 and the heat member 20. Further, the method for manufacturing the power controller apparatus 1 includes a close contacting step in which the thermal conductive member 50 is brought into close contact with both the heat dissipation member 10 and the heat member 20 by the snap fit 40. In one example, the manufacturing method is executed in an order of the arranging step and the snap fitting step. The close contact step is performed at the same time as the snap fitting step. Further, the close contact step is continuously executed even after the snap fitting step.

In the arranging step, a plurality of parts including the heat dissipation member 10, the thermal conductive member 50, and the heat member 20 are positioned in a regular positional relationship. At this time, a plurality of parts are positioned so as to avoid interference between the snap fit 40 and the thermal conductive member 50.

In the snap-fit step, the heat dissipation member 10 and the heat member 20 transfer from a non-engaged state to an engaged state by utilizing an elastic deformation of the snap-fit 40. In the snap-fit step, the heat dissipation member 10 and the heat member 20 are moved so as to gradually approach each other from the non-engaged state to the engaged state. The heat dissipation member 10 and the heat member 20 are relatively moved so as to gradually approach each other along, for example, the stacking direction LMD. In the snap-fit step, the elastic arm 35 is elastically deformed due to an interference between the engaging convex portion 36 and the heat dissipation member 10. As a result, the engaging convex portion 36 and the engaging concave portion 16 can be relatively moved to the engaging position. In other words, an elastic piece 43 is deformed by the interference between the heat dissipation member 10 and the heat member 20. As a result, the engaging step portion 41 and the engaging step portion 42 relatively move to the engaging position and mesh with each other.

In the snap-fit step, the thermal conductive member 50 is brought into close contact with both the heat dissipation member 10 and the heat member 20. Further, this close contact state is stably maintained by the elastic force provided by the snap fit 40. In this embodiment, the heat dissipation member 10 and the heat member 20 are connected only by the snap fit 40. The heat dissipation member 10 and the heat member 20 are connected only by the snap fit 40 without providing any fastening member such as a bolt and a nut. Moreover, the thermal conductive member 50 is in close contact with both the heat dissipation member 10 and the heat member 20 only by the snap fit 40.

The snap fit 40 includes a plurality of elastic arms 35. The elastic arm 35 extends from a heat dissipating surface of the heat member 20. In other words, the elastic arm 35 protrudes from the lower surface of the heat member 20. The plurality of elastic arms 35 define a minimum width Wmin. The minimum width Wmin is defined by a distance between top portions of the engaging protrusions 36. The thermal conductive member 50 has a width W50. The width W50 is smaller than the minimum width Wmin defined by the snap fit 40 (W50<Wmin). Thereby, the thermal conductive member 50 can be protected from the elastic arm 35. In addition, the width of the electrical component 31 is smaller than the width W50. Such a setting maintains a cross-sectional area that contributes to heat dissipation from the electrical component 31, and suppresses a bottleneck of heat dissipation.

In the case that the snap fit 40 allows reversible elastic deformation, the snap fit 40 may allow a release operation from the engaged state to the non-engaged state. In the case that the snap fit 40 does not allow reversible elastic deformation, the snap fit 40 does not allow the release operation from the engaged state to the non-engaged state. Further, the heat dissipation member 10 and the heat member 20 may be transferred from the non-engaged state to the engaged state by sliding and moving with respect to the orthogonal direction PPD.

According to the embodiment described above, the heat dissipation member 10 and the heat member 20 can be assembled by a one-touch operation of simply moving the heat dissipation member 10 and the heat member 20 to a regular position. Moreover, the thermal conductive member 50 is arranged. As a result, a high thermal transfer coefficient can be obtained between the heat dissipation member 10 and the heat member 20. As a result, the thermal transfer coefficient between the heat dissipation member 10 and the heat member 20 is not impaired while obtaining a simple assembly operation by the snap fit 40. In other words, it is possible to provide the power controller apparatus that obtains both ease of assembly work and low thermal resistance.

### Second Embodiment

This embodiment is a modification based on the preceding embodiment. In the preceding embodiment, the switch module 21 as the heat member 20 includes an electrical component 31. In addition to this, the heat member 20 may include an internal thermal conductive member 232 for heat dissipation. The disclosure in this embodiment can be combined with the preceding embodiment and the succeeding embodiment.

As shown in FIG. 5, the switch module 21 includes an internal thermal conductive member 232. The internal thermal conductive member 232 is thermally connected to the electrical component 31. The internal thermal conductive member 232 provides a heat dissipation path from the electrical component 31. The thermal conductive member 50 is arranged so as to come into contact with the thermal conductive member 232. Also in this embodiment, the same effect as that of the preceding embodiment can be obtained.

### Third Embodiment

This embodiment is a modification based on the preceding embodiment. In the preceding embodiment, the switch module 21 is exemplified as the heat member 20. Alternatively, the heat member 20 may be another heat member 20 in the power controller apparatus 1. The heat member 20 may be, for example, an inductor module 22, a capacitor module 23, a circuit module 24, a sensor module 25, or a bus bar module 26. The disclosure in this embodiment can be combined with the preceding embodiment and the succeeding embodiment.

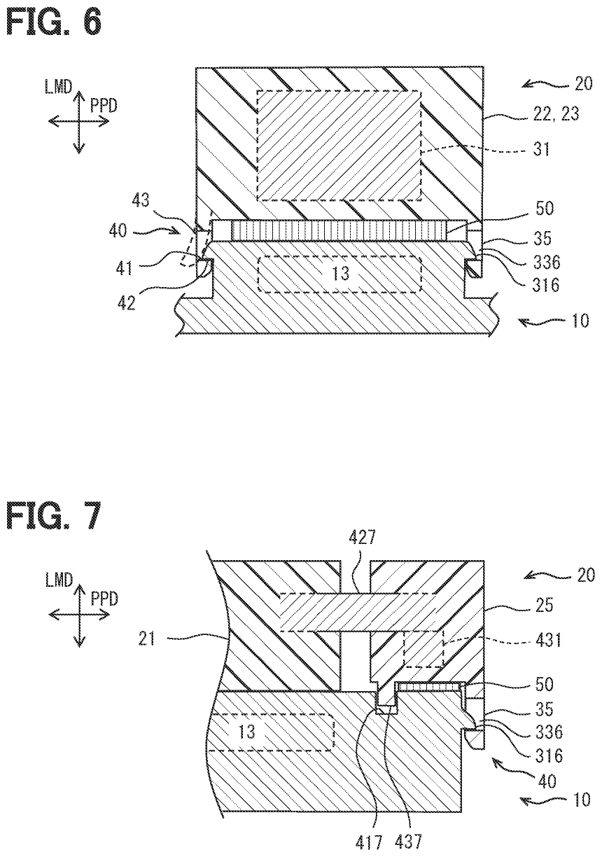

In FIG. 6, the inductor module 22 or the capacitor module 23 is exemplified as the heat member 20. In the case that the heat member 20 is the inductor module 22, the electric component 31 is an inductor. In the case that the heat member 20 is the capacitor module 23, the electric component 31 is a capacitor.

The heat member 20 has an engaging recess 336 provided in the elastic arm 35. The engaging recess 336 is provided by a through hole that penetrates the elastic arm 35. The engaging recess 336 provides an engaging step portion 41. The heat dissipation member 10 has an engaging convex portion 316. The engaging protrusion 316 provides an engaging step portion 42. In this embodiment, the snap fit 40 has an engaging step portion 41 provided by an engaging recess 336 disposed on the heat member 20 which is one of the heat member 20 and the heat dissipation member 10. The snap fit 40 has an engaging step portion 42 provided by an engaging convex portion 316 disposed on the heat dissipation member 10 which is the other side of the heat member 20 and the heat dissipation member 10. The snap fit 40 fixes the heat member 20 and the heat dissipation member 10 by catching and hooking the two engaging step portions 41 and 42 each other. Also in this embodiment, the same effect as that of the preceding embodiment can be obtained.

### Fourth Embodiment

This embodiment is a modification based on the preceding embodiment. The disclosure in this embodiment can be combined with the preceding embodiment.

In FIG. 7, the sensor module 25 has a bus bar 427 extending from the switch module 21. The sensor module 25 has a current sensor 431 that detects the current flowing through the bus bar 427. Also in this embodiment, the thermal conductive member 50 is arranged between the sensor module 25 and the heat dissipation member 10.

The sensor module 25 is connected to the heat dissipation member 10 by the snap fit 40. The snap fit 40 is provided by the elastic arm 35, the engaging recess 336, and the engaging protrusion 316 in the preceding embodiments. Further, a rigid fitting portion is formed between the sensor module 25 and the heat dissipation member 10. The rigid fitting portion, in combination with the elastic snap fit 40, connects the sensor module 25 to the heat dissipation member 10. The fitting portion includes a convex portion 437 disposed on the sensor module 25 and a concave portion 417 disposed on the heat dissipation member 10. The convex portion and the concave portion for providing the fitting portion may be provided in an opposite relation. Also in this embodiment, the same effect as that of the preceding embodiment can be obtained.

### Other Embodiments

The disclosure in this specification, drawings and the like is not limited to the exemplified embodiments. The disclosure encompasses the illustrated embodiments and variations thereof by those skilled in the art. For example, the present disclosure is not limited to the combinations of components and/or elements shown in the embodiments. The present disclosure may be implemented in various combinations. The present disclosure may have additional members which may be added to the embodiments. The present disclosure encompasses omission of the components and/or elements of the embodiments. The present disclosure encompasses the replacement or combination of components and/or elements between one embodiment and another. The disclosed technical scope is not limited to the description of the embodiment. Several technical scopes disclosed are indicated by descriptions in the claims and should be understood to include all modifications within the meaning and scope equivalent to the descriptions in the claims.

The disclosure in the specification, drawings and the like is not limited by the description of the claims. The disclosures in the specification, the drawings, and the like encompass the technical ideas described in the claims, and further extend to a wider variety of technical ideas than those in the claims. Hence, various technical ideas can be extracted from the disclosure of the specification, the drawings, and the like without being bound by the description of the claims.

In the above embodiment, the switch module 21, the inductor module 22, the capacitor module 23, or the sensor module 25 has been exemplified. Alternatively, the snap fit 40 may be applied to the circuit module 24 or the bus bar module 26. In addition, the snap fit 40 may be provided as a fixing device between the plurality of heat members 20 and the heat dissipation member 10. Therefore, the snap fit 40 may be applicable to one or a plurality of a switch module 21, an inductor module 22, a capacitor module 23, a circuit module 24, a sensor module 25, and a bus bar module 26.

In the above embodiment, the snap fit 40 provides the elastic piece 43 by the elastic arm 35 disposed on the heat member 20. Alternatively, the snap fit 40 may include elastic arms disposed on the heat dissipation member 10. Further, the snap fit 40 may be provided with elastic arms on both the heat dissipation member 10 and the heat member 20.

What is claimed is:

1. A power controller apparatus including a plurality of parts, the power controller apparatus comprising:
a heat member which requires heat dissipation by generating heat or receiving heat;
a heat dissipation member which contributes to dissipate heat from the heat member;
a snap fit which connects the heat member and the heat dissipation member; and
a thermal conductive member arranged between the heat member and the heat dissipation member, wherein
the thermal conductive member includes a filler which has anisotropy with respect to thermal conductivity, and is oriented so as to exhibit high thermal conductivity in a stacking direction between the heat member and the heat dissipation member.

2. The power controller apparatus claimed in claim 1, wherein
the snap fit includes:
an engaging step portion provided by a convex portion or a concave portion disposed on one of the heat member and the heat dissipation member; and
an engaging step portion provided by a concave portion or a convex portion disposed on the other side of the heat member and the heat dissipation member, wherein
the heat member and the heat dissipation member are fixed by catching and hooking the engaging step portions each other.

3. The power controller apparatus claimed in claim 1, wherein
the heat member includes one or a plurality of a switch module containing a semiconductor switch element, an inductor module containing an inductor, a capacitor module containing a capacitor, a circuit module containing a circuit, and a sensor module containing a current sensor, and a bus bar module containing a bus bar.

4. The power controller apparatus claimed in claim 1, wherein
the filler is fibrous.

5. The power controller apparatus claimed in claim 1, wherein
the filler is elastically deformed by force applied by the snap fit.

6. The power controller apparatus claimed in claim 1, wherein
a width (W50) of the thermal conductive member is smaller than a minimum width (Wmin) defined by the snap fit (W50<Wmin).

7. The power controller apparatus claimed in claim 1, wherein
the heat member and the heat dissipation member are connected only by the snap fit without providing a fastening member.
